(19) United States
(12) Patent Application Publication
(10) Pub. No.: US 2025/0076051 A1
(43) Pub. Date: Mar. 6, 2025

(54) MEMS SENSOR AND METHOD FOR COMPENSATING FOR SYSTEMATIC MEASUREMENT DEVIATIONS IN MEMS SENSORS

(71) Applicant: Robert Bosch GmbH, Stuttgart (DE)

(72) Inventor: Andrea Opreni, Reutlingen (DE)

(21) Appl. No.: 18/785,341

(22) Filed: Jul. 26, 2024

(30) Foreign Application Priority Data
Sep. 5, 2023 (DE) 10 2023 208 543.7

(51) Int. Cl. G01C 19/5712; G01C 19/5656

(52) U.S. Cl. CPC G01C 19/5712; G01C 19/5656

(57) ABSTRACT

A MEMS sensor, in particular a MEMS acceleration sensor or MEMS inertial sensor. The MEMS sensor includes: a substrate having a main extension plane; a seismic mass suspended movably with respect to the substrate in at least a z-direction perpendicular to the main extension plane; and a sensor device for detecting a measurement signal dependent on the position of the seismic mass in relation to the substrate. The MEMS sensor also includes: at least two resonators, which are suspended resiliently movably in the z-direction in relation to the substrate; and a controllable electrode arrangement, which is configured to resonantly excite each of the at least two resonators to generate mechanical resonant vibrations, and to capacitively detect a disturbance variable dependent on at least one resonance frequency of the resonant vibrations.

### CROSS REFERENCE

The present application claims the benefit under 35 U.S.C. § 119 of German Patent Application No. DE 10 2023 208 543.7 filed on Sep. 5, 2023, which is expressly incorporated herein by reference in its entirety.

### FIELD

The present invention relates to a MEMS sensor (MEMS: micro-electromechanical system, microsystem), such as a MEMS inertial sensor or MEMS acceleration sensor. The present invention furthermore relates to a method for compensating for systematic measurement deviations which typically occur in MEMS sensors.

### BACKGROUND INFORMATION

An acceleration sensor is often formed as a capacitive sensor. The seismic mass of the capacitive acceleration sensor can be formed as an asymmetrical rocker. A micromechanical acceleration sensor with a seismic mass formed as an asymmetrical rocker is described, for example, in European Patent No. EP 0 773 443 A1.

German Patent Application No. DE 10 2020 205 616 A1 describes an acceleration sensor with a sensor device which generates a measurement signal depending on the position of the movable mass. The sensor device may, for example, have a total of four upper and lower electrodes, wherein the upper electrodes are electrically connected to the lower electrodes, in particular in pairs, in such a way that a difference signal corresponding to the difference between a first capacitance and a second capacitance can be detected and evaluated.

### SUMMARY

An object of the present invention is to provide an improved MEMS sensor and an improved method for compensating for systematic measurement deviations in MEMS sensors.

The aforementioned object may be achieved by features of the present invention. Advantageous example configurations of the present invention are disclosed herein.

A MEMS sensor, in particular a MEMS acceleration sensor or MEMS inertial sensor, comprises a substrate having a main extension plane, a seismic mass in relation to which the substrate is suspended movably, and a sensor device for detecting a measurement signal dependent on the position of the seismic mass in relation to the substrate. According to an example embodiment of the present invention, in addition to the sensor device, at least two resonators are provided, which are suspended resiliently movably in relation to the substrate in a z-direction perpendicular to the main extension plane. For this purpose, in embodiments, the at least two resonators may, for example, be suspended resiliently from the seismic mass or from an anchoring fixedly connected to the substrate. A controllable electrode arrangement designed to excite each of the at least two resonators resonantly, in particular corresponding to a resonance frequency of the resonators, and to capacitively detect a disturbance variable dependent on the resonance frequency of the resonantly excited resonator. For controlling the electrode arrangement, it can be connected to a control and evaluation unit, which is furthermore designed to compensate for systematic measurement deviations in the measurement signal of the sensor device depending on the detected disturbance variable.

The resonance frequencies of the excited resonators are dependent on mechanical stresses or deformations of the substrate, in particular due to the electrostatic spring-softening effect, so that the capacitive detection of the disturbance variable provides an independent measure for unknown deformations, in particular those that only occur during operation. This makes it possible to identify defects or to determine the disturbance variable dependent thereon for the purpose of compensating for deviations in the measurement signal of the sensor device during operation and/or during calibration, in particular in real time.

The resonance frequencies are determined by the mechanical vibration spectrum of the resonators. In particular in comparison to conventional sensors, the control and evaluation unit of the MEMS sensor is additionally designed to control the electrode arrangement for the resonant excitation of the resonators in the corresponding frequency range so that they are excited to corresponding resonance vibrations.

The MEMS sensor, in particular the MEMS acceleration sensor or MEMS inertial sensor, is designed to compensate for systematic measurement deviations. The substrate forms a layer in a layer structure of the MEMS sensor and thus in particular represents deformations of the layer structure that are caused by the production or assembly of the MEMS sensor or that only occur during operation of the MEMS sensor. Preferably, the at least two resonators are formed by recesses in a layer of the layer structure.

According to one possible embodiment of the present invention, the seismic mass is designed as a deflectable, in particular asymmetrical, rocker, which is anchored to the substrate via at least one torsion spring so as to be adjustable about a torsion axis.

According to an example embodiment of the present invention, the at least two resonators are preferably laterally spaced apart from one another in a plane perpendicular to the z-direction of the layer structure (or parallel to the main extension plane), so that even slight deviations from a plane-parallel layer arrangement can be reliably detected. Particularly preferred is an arrangement of the resonators on opposite sides of the torsion axis, in particular mirror-symmetrical with respect to the torsion axis.

Preferably, according to an example embodiment of the present invention, each resonator is assigned a drive electrode and a detection electrode in such a way that the respectively assigned resonator can be resonantly excited by means of the drive electrode and the measured variable dependent on the resonance frequency of the resonantly excited resonator can be detected by means of the detection electrode. Separate detection electrodes advantageously increase the measurement accuracy with which the disturbance variable dependent on the resonance frequency of the resonantly excited resonator can be detected.

According to an example embodiment of the present invention, tor compensating for systematic measurement deviations, the resonators are preferably designed as structural elements suspended on one or both sides, in particular substantially in the form of a beam, a finger, a piston, or a fork. The structural elements are further preferably formed in the same way so that the at least two resonators, in particular the four resonators provided in embodiments, have substantially the same mechanical vibration spectrum, i.e. in particular in the absence of mechanical stresses.

In one possible example embodiment of the electrode arrangement of the present invention, the drive electrodes and the detection electrodes are arranged in a plane substantially parallel to the main extension plane, in particular on the substrate 40. Alternatively, sandwich-like configurations are also possible, in which the drive electrodes and the detection electrodes are arranged opposite one another in two planes substantially parallel to the main extension plane. In this configuration, the resonators are arranged between the drive electrodes and the detection electrodes and spaced apart therefrom in the z-direction.

In example embodiments of the present invention, at least three, preferably four, resonators are provided which are laterally spaced apart from one another in the plane perpendicular to the stack direction in an arrangement which deviates from a collinear arrangement. In other words, the resonators are arranged in the plane such that surface curvatures of the substrate in the main extension plane, in particular in the x-direction and y-direction, can be detected.

For generating the measurement signal of the sensor device, the position of the movable mass in relation to at least one spatial direction, for example in relation to the z-direction, is detected capacitively. The resonators are, for example, resiliently fastened to the seismic mass of the MEMS sensor so that the movement of the resonators is coherent with the movement of the seismic mass.

According to an example embodiment of the present invention, in a method for compensating for systematic measurement deviations of the MEMS sensor, the at least two resonators are excited to mechanical resonance vibrations by means of the electrode arrangement already described, and the disturbance variable dependent on the resonance frequency of the resonance vibrations is detected capacitively. Systematic measurement deviations in the measurement signal of the sensor device are compensated depending on the detected disturbance variable.

Due to the electrostatic spring-softening effect, the measured variable dependent on the resonance frequency of the resonantly excited resonator depends in particular on the size of the gap or the deflection of the resonators in relation to the substrate, in particular on any deformation of the substrate in relation to the position of the resonators. The thus detected disturbance variable therefore provides a signal suitable for compensating for the output signal, which signal also comprises disturbance variables of unknown origin which may occur only during assembly of the MEMS sensor and/or during operation of the MEMS sensor.

According to an example embodiment of the present invention, preferably, the systematic measurement deviations in the output signal of the MEMS sensor are compensated for analogly or digitally by means of the detected disturbance variable.

Further preferably, according to an example embodiment of the present invention, for the resonant excitation of the resonator(s), a pulsed or continuous excitation signal, in particular a harmonic excitation signal or an excitation signal with a temporally variable frequency, is applied to the electrode arrangement, in particular to the drive electrodes.

Further details and advantages of the present invention are explained in more detail below with reference to the exemplary embodiments shown in the figures.

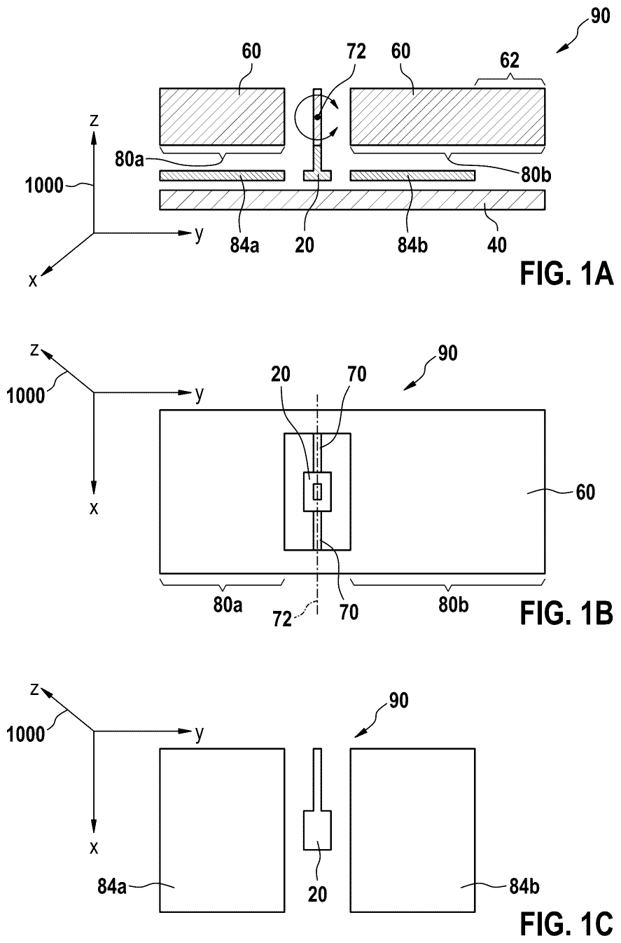

FIG. 1A to 1C show a cross-section and two plan views for illustrating an acceleration sensor, according to an example embodiment of the present invention.

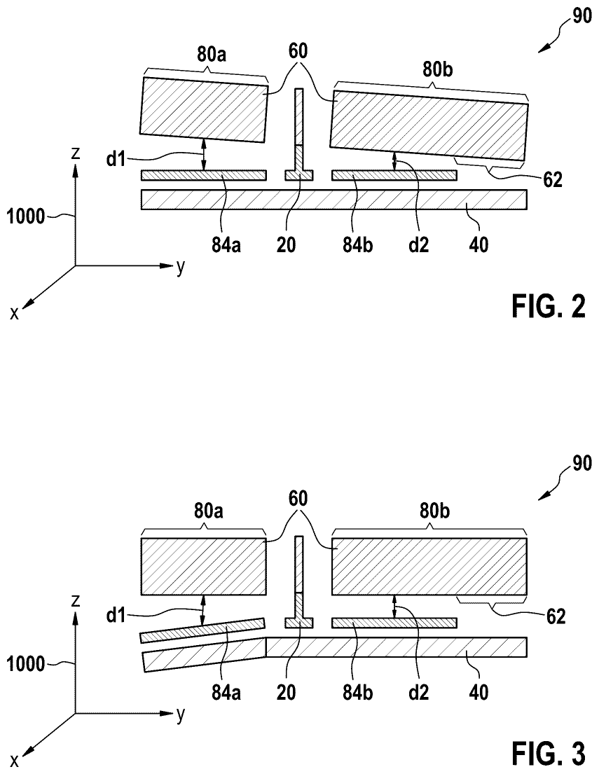

FIG. 2 shows a cross-section through the acceleration sensor of FIG. 1A to 1C in order to illustrate its functional principle.

FIG. 3 shows a cross-section through the acceleration sensor of FIG. 1A to 1C with a mechanical stress being exerted on the acceleration sensor according to an example embodiment of the present invention.

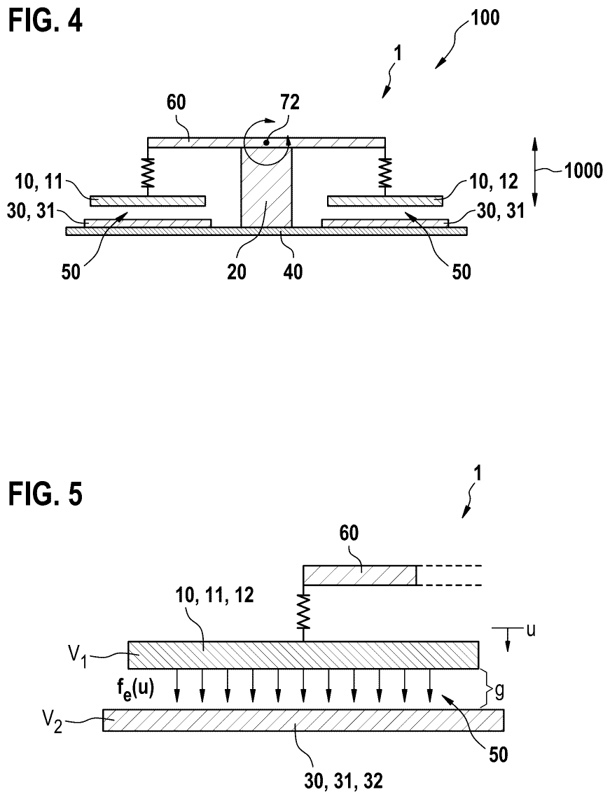

FIG. 4 schematically shows in a schematic sectional view the mechanical operating principle of a MEMS sensor, which is designed to compensate for systematic measurement deviations on the basis of two resonantly excitable resonators, according to an example embodiment of the present invention.

FIG. 5 shows details of the mechanical operating principle of FIG. 4 in a schematic sectional view.

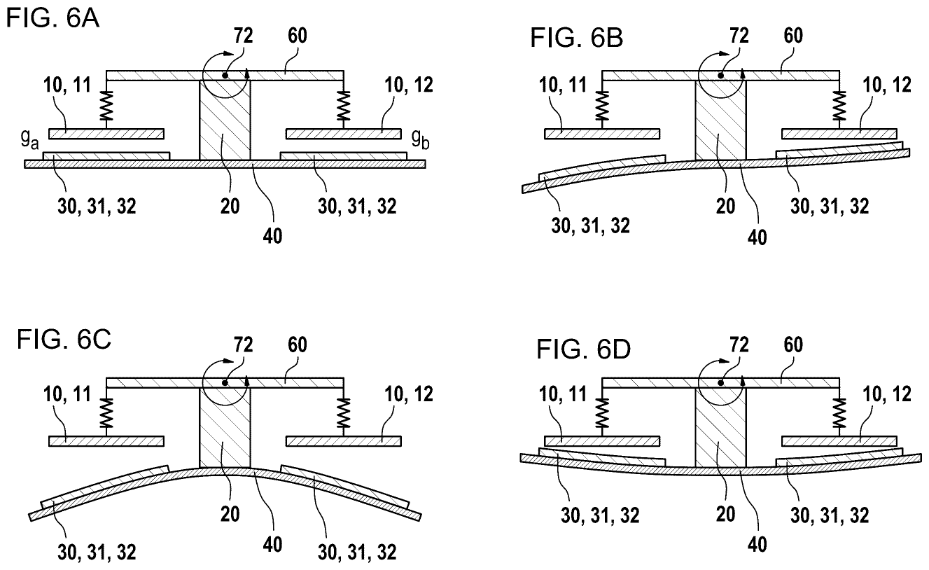

FIG. 6A to 6D show various exemplary configurations according to the present invention that can be understood on the basis of the presented mechanical operating principle.

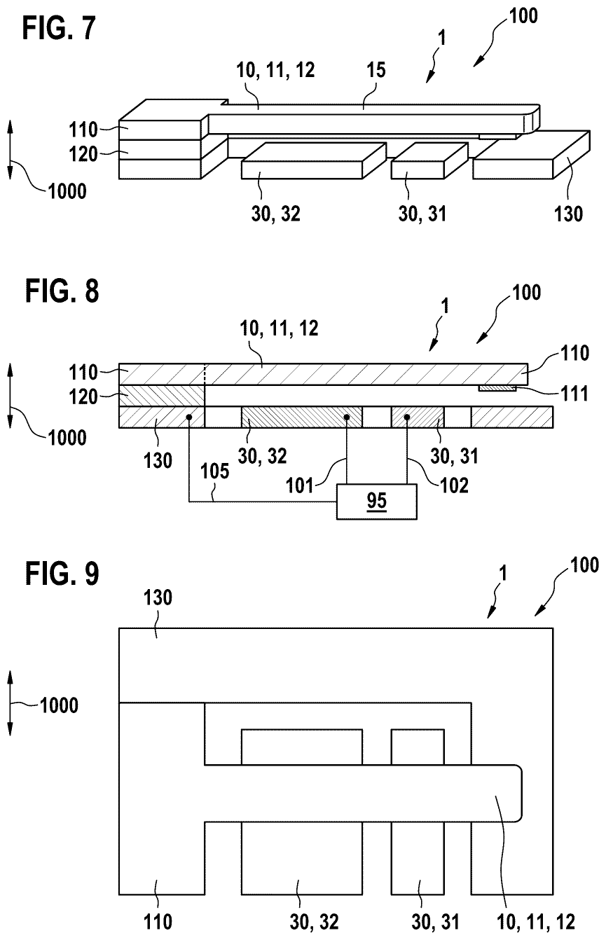

FIG. 7 shows an implementation of a resonator in a multilayer composite of a MEMS sensor in a perspective view, according to an example embodiment of the present invention.

FIG. 8 shows the resonator of FIG. 7 in a sectional view.

FIG. 9 shows the resonator of FIG. 7 in a plan view.

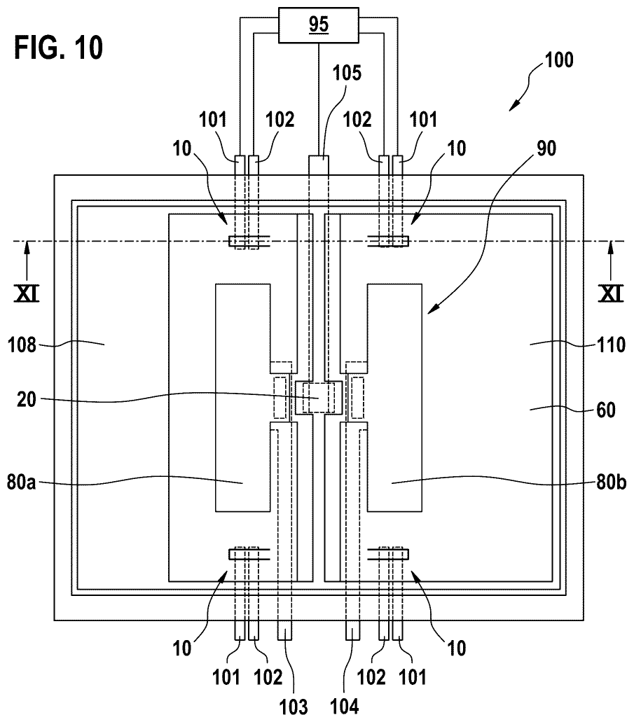

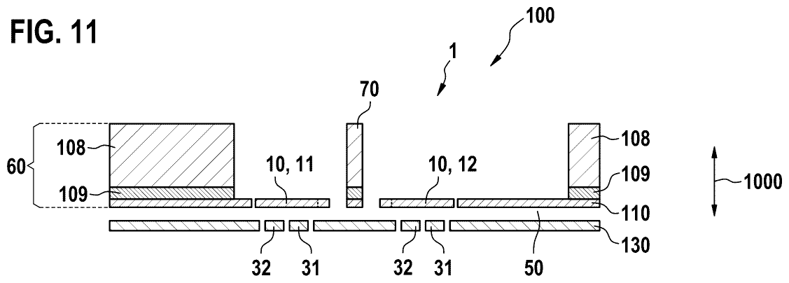

FIG. 10 shows a further exemplary embodiment of a MEMS sensor according to the present invention designed to compensate for systematic measurement deviations in a plan view.

FIG. 11 shows the MEMS sensor of FIG. 10 in a sectional view.

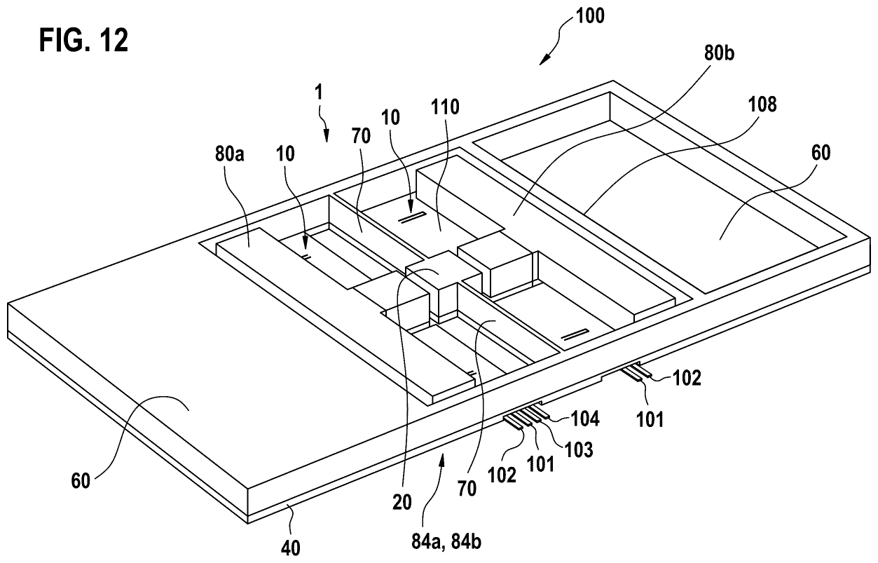

FIG. 12 shows a MEMS sensor of FIG. 10 in a perspective view.

FIG. 13 shows in detail a resonator of the MEMS sensor of FIG. 10.

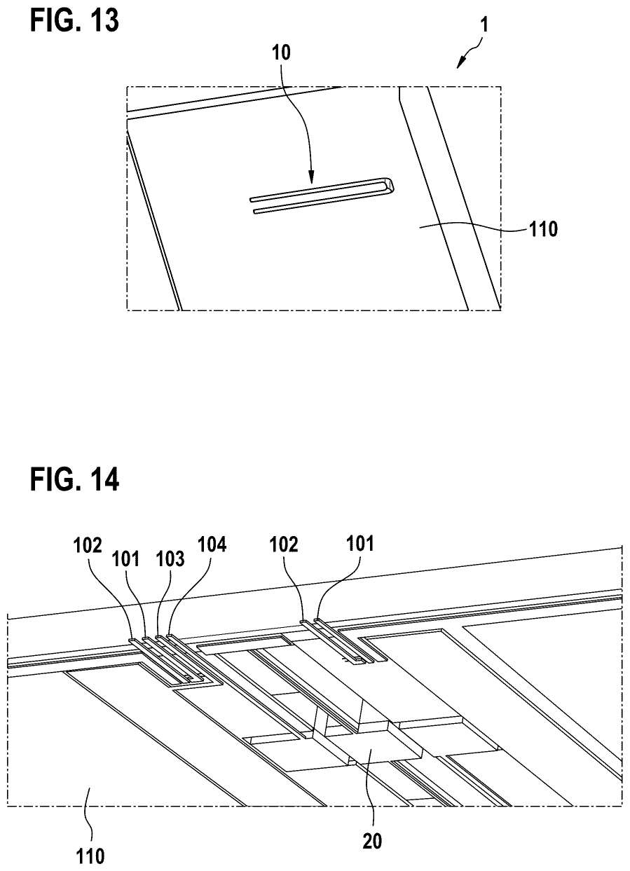

FIG. 14 shows in detail a rear side of the MEMS sensor with channel structure for electrical contacting, according to an example embodiment of the present invention.

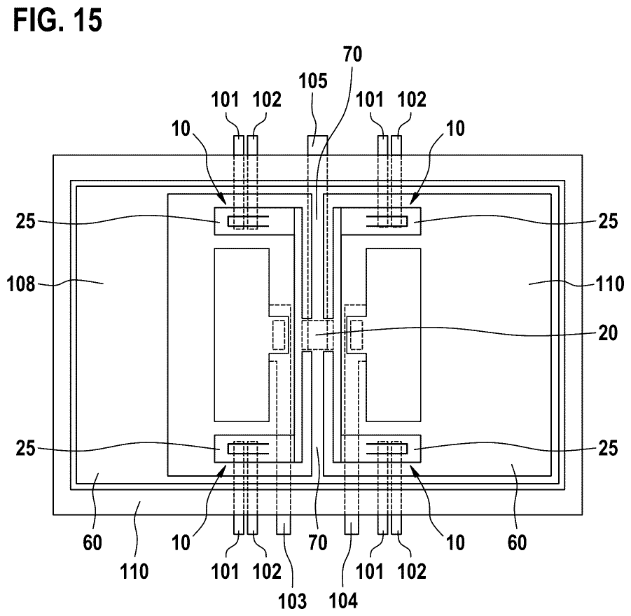

FIG. 15 shows a further exemplary embodiment of the MEMS sensor of the present invention in a plan view.

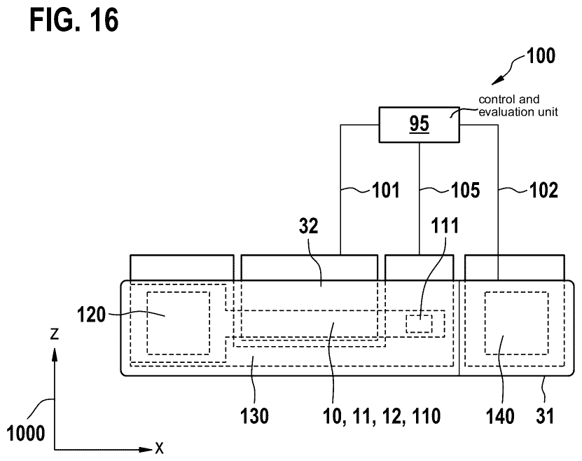

FIG. 16 shows a further implementation of a resonator according to an example embodiment of the present invention in a multilayer composite of a MEMS sensor in a plan view.

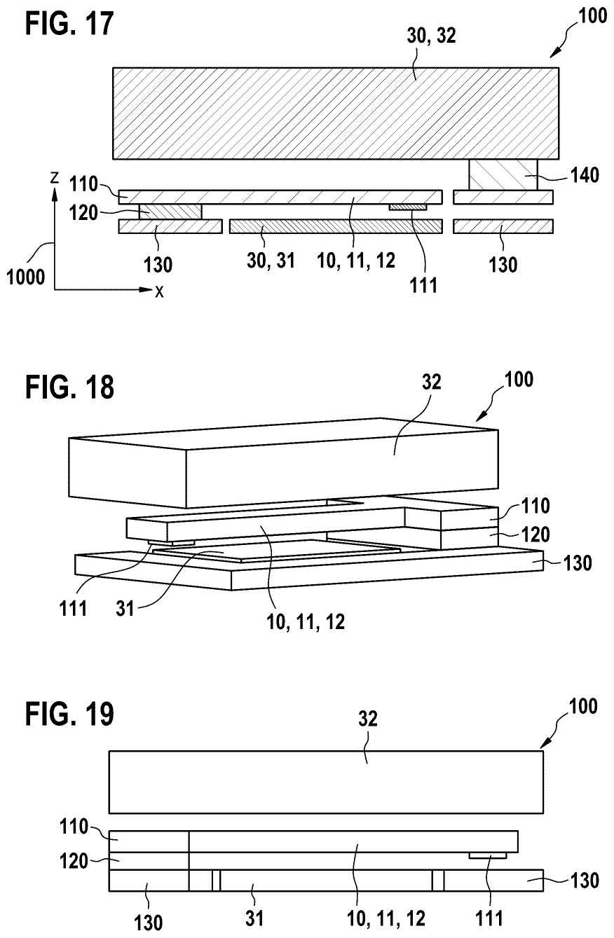

FIG. 17 shows the resonator of FIG. 16 in a sectional view.

FIG. 18 shows the resonator of FIG. 16 in a perspective view.

FIG. 19 shows the resonator of FIG. 16 in a side view.

Identical or corresponding elements are provided with the same reference signs in all figures.

### DETAILED DESCRIPTION OF EXAMPLE EMBODIMENTS

FIG. 1A to 1C show a cross-section and two plan views for illustrating an acceleration sensor with a sensor device 90 for detecting a measurement signal, which is generated depending on an inertial force and/or acceleration force acting on the sensor.

The capacitive acceleration sensor shown in cross-section in FIG. 1A is designed to detect an acceleration oriented perpendicularly to a wafer or a flat substrate 40 (z-direction) and to determine a variable corresponding to the acceleration. For this purpose, a seismic mass 60 formed as an asymmetrical rocker is adjustably arranged above the substrate 40. The seismic mass 60 is connected via two torsion springs 70 (see FIG. 1B) to an anchor 20, which is fixedly arranged on the substrate 40. The torsion springs 70 (cf. in particular FIG. 1B) extend along a torsion axis 72, about which the seismic mass 60 taking the form of a rocker is adjustable.

The seismic mass 60 comprises a first upper electrode 80a arranged on a first side of the torsion axis 72 and a second upper electrode 80b arranged on the second side of the torsion axis 72. Due to an additional mass 62, the second electrode 80b can have a greater mass than the first measuring electrode 80a.

The counter-electrodes, referred to as first and second lower electrodes 84a, 84b, are fixedly attached to the substrate 40. The sensor principle of the acceleration sensor is thus based on a spring-mass system in which the movable seismic mass 60 forms two plate capacitors with the counter-electrodes 84a and 84b fastened on the wafer 40. The counter-electrodes 24a and 24b shown in a plan view in FIG. 1C are arranged in relation to the electrodes 80a and 80b of the seismic mass 60 such that the position of the seismic mass 60 in relation to the substrate 40 can be ascertained by evaluating a first capacitance between the electrode 80a and the associated first counter-electrode 84a and a second capacitance between the electrode 80b and the associated second counter-electrode 84b.

FIG. 2 shows a cross-section through the acceleration sensor of FIG. 1A to 1C in order to illustrate its functional principle. If the acceleration sensor experiences an acceleration in the z-direction 1000, as shown in FIG. 2, a force directed in the direction of the substrate 40 will act on the second upper electrode 80b due to the additional mass 62. Due to this acceleration, the seismic mass 60 taking the form of a rocker is shifted about the torsion axis 72 such that a first average distance d1 between the first upper electrode 80a and the first lower electrode 84a increases and a second average distance d2 between the second upper electrode 80b and the second lower electrode 84b decreases.

The changes in the capacitances of the two capacitors formed by the upper electrodes 80a and 80b and the lower electrodes 84a and 84b, which changes correspond to the changes in the distances d1 and d2, can subsequently be evaluated to determine or ascertain the acting acceleration. Since methods for evaluating capacitance changes are conventional, they will not be discussed further here.

FIG. 3 shows a cross-section through the acceleration sensor of FIG. 1A to 1C with a mechanical stress being exerted on the acceleration sensor.

In FIG. 3, mechanical stress is acting on the wafer or on the substrate 40 which bends the substrate 40 asymmetrically along the y-direction. Due to the asymmetrical bending of the substrate 40, the first average distance d1 between the first upper electrode 80a and the first lower electrode 84a changes, for example. Likewise, the second average distance d2 between the second upper electrode 80b and the second lower electrode 84b may increase or decrease under the influence of mechanical stress.

Thus, in the acceleration sensor, a mechanical stress exerted, for example, via a force or via a pressure on at least a part of the acceleration sensor, in particular on a subunit of the housing or substrate 40, can cause a capacitance change in the capacitors composed of the upper electrodes 80a and 80b and the lower electrodes 84a and 84b. As a rule, an evaluation device (not shown) of the acceleration sensor cannot distinguish the capacitance change caused by a stress influence from a capacitance change triggered by an acceleration of the acceleration sensor.

It is desirable that, in the absence of external excitation or force application, inertial sensors or acceleration sensors do not generate any measurement signals that could be incorrectly interpreted by the evaluation electronics as an inertial force or acceleration acting on the sensor. However, in practical application, measurement signals from such commonly formed sensor devices are often characterized by systematic measurement deviations, which are also referred to as bias or offset and are caused, for example, by process-related defects and/or stresses, deformation of the layer structure of the sensor during production and/or by assembly errors. However, measurement deviations caused by random effects, such as incorrect assembly of the sensor, often cannot be determined in advance.

FIG. 4 shows in a schematic sectional view the mechanical operating principle of a device 1 for detecting a disturbance variable, which is correlated with typically occurring systematic measurement deviations of a MEMS sensor, in particular of a MEMS inertial sensor or MEMS acceleration sensor. The device 1 is realized in a multilayer composite of a MEMS sensor 100 and comprises at least two resonators 10, 11, 12 that can be excited to resonant natural vibrations.

In the example shown, the at least two resonators 10, 11, 12 are resiliently suspended from a seismic mass 60, which is fastened to an anchor 20 so as to be movable about a torsion axis 72. The anchor 20 is fixedly connected to a stationary, flat substrate 40 in such a way that a gap 50 is formed between the substrate 40 and the resonators 10, 11, 12. The main extension plane of the substrate 40 is perpendicular to the drawing plane. The resonators 10, 11, 12 are configured to be excited to resonance vibrations by means of an electrode arrangement 30. For this purpose, the electrode arrangement 30 comprises two drive electrodes 31, which are arranged on the substrate 40 and opposite the face sides of the resonators 10, 11, 12.

The resonant excitation of the resonators 10, 11, 12 takes place by controlling or applying voltage to the electrode arrangement 30, in particular to the drive electrodes 31. For this purpose, a control and evaluation unit 95 (cf. in particular FIG. 10) is provided, which is not explicitly shown in FIG. 4 and is connected to the electrode arrangement 30.

For example, the resonant excitation of the resonators 10, 11, 12 takes place continuously during operation of the MEMS sensor 100 by means of a harmonic drive signal or, alternatively, only for a short period of time during calibration of the MEMS sensor 100, in particular before putting the MEMS sensor 100 into operation. Alternatively, the excitation may take place by means of a so-called chirp signal, i.e. an excitation signal with a temporally variable frequency, in particular a temporally increasing or decreasing frequency.

The electrode arrangement 30 is furthermore designed to capacitively detect a disturbance variable dependent on a resonance frequency of the resonantly excited resonator 10, 11, 12. Such a disturbance variable may, for example, be caused by a relative shift of the resonance frequencies of the two resonators 11, 12, which shift may in particular be caused by mechanical stresses. The capacitive determination of such a disturbance variable takes place in particular for the purpose of compensating for systematic measurement deviations in a measurement signal of the MEMS sensor 100, which measurement signal is provided independently by a sensor device 90 of the MEMS sensor 100. The sensor device 90 can be designed in a usual manner, in particular as described above with reference to FIG. 1 to 3, for detecting a measurement signal dependent on the position of the seismic mass in relation to the substrate 40. On the basis of the measurement signal of the sensor device 90, a measure of an acceleration acting on the MEMS sensor 100 can be derived.

In possible embodiments, the detection of the resonance frequency or resonance frequencies or a disturbance variable dependent thereon takes place by means of the drive electrodes 31 themselves; however, separate detection electrodes 32, which are not explicitly shown in FIGS. 4 and 5, are preferably provided for this purpose.

The resonators 10, 11, 12 are preferably structurally largely identical so that they form mechanical resonance structures which substantially have the same eigenspectrum or resonance spectrum, in particular within the scope of manufacturing precision.

The resilient suspension of the resonators 10, 11, 12 is preferably provided by the structural design of the resonators 10, 11, 12 themselves and their connection to the seismic mass 60 or, alternatively, to an anchoring 25 that is stationary in relation to the substrate 40 (cf. in particular FIG. 15).

Due to the electrostatic spring-softening effect, which is explained in more detail below with reference to FIG. 5, the disturbance variable dependent on the resonance frequency of the resonantly excited resonator 10, 11, 12 is correlated with the size of the gap 50 or the deflection of the resonators 10 in relation to the substrate 40, in particular with any deformation of the substrate 40 in relation to the position of the resonators 10. Since a direct measurement of the deflection is difficult to realize, in particular with MEMS sensors 100, such as MEMS inertial sensors, MEMS acceleration sensors, or MEMS yaw rate sensors, the disturbance variable dependent on the resonance frequency or resonance frequencies is detected capacitively. The detected disturbance variable depends on the changing capacitances between the resonators 10, 11, 12 and the electrode arrangement 30, in particular the detection electrodes 32.

In cases in which no separate detection electrodes 32 are provided, the capacitance between the resonators 10 and the drive electrodes 31 is detected accordingly. The change in the capacitances can be correspondingly demodulated in order in particular to obtain a direct current measurement signal representing the disturbance variable.

The electrostatic spring-softening effect is schematically illustrated in FIG. 5. If a potential difference is applied between the resonators 10, 11, 12 and the electrode arrangement 30, surface charges typically form on opposing surfaces of the electrode arrangement 30 and of the resonators 10, 11, 12. These surface charges generate an attractive interaction between the electrode arrangement 30 and the resonators 10, 11, 12, which depends on a plurality of parameters, such as the relative local distance between the respective resonator 10, 11, 12 and the electrode arrangement 30. The force thus generated between the resonator 10, 11, 12 and the electrode arrangement 30 is typically a smooth function with respect to the last-mentioned parameter. The relative distance between the resonator 10, 11, 12 and the electrode arrangement 30 can be expressed as the sum of the dynamic deflection of the resonator 10, 11, 12 in relation to the electrode arrangement 30 and the width of the gap 50. By means of the Taylor expansion with respect to the dynamic deflection, a linear term which depends on the width of the gap 50 is obtained.

The movement of each resonator 10, 11, 12 is determined by a movement equation of the form

$$m \ddot{u} + ku = {f}_{e} ( u ; g ) ,$$

where m denotes the mass of the resonator 10, 11, 12, u denotes the dynamic deflection, g denotes the width of the gap 50, and k denotes the stiffness of the resonator 10 (ü denotes, in the usual way, the second derivative of the dynamic deflection u with respect to time). The force f_{e(u; g)} is given by

$${f}_{e ( u ; g )} = \frac{1}{2} \frac{ϵ A}{{( g - u )}^{2}} {( {V}_{1} - {V}_{2} )}^{2} ,$$

Here, ε denotes the dielectric constant, V₁ denotes the voltage applied to the resonator 10, 11, 12, and V₂ denotes the voltage applied to the electrode arrangement 30. The Taylor expansion of the force f_{e(u; g)} with respect to the dynamic deflection u results in:

$${f}_{e ( u ; g )} = {f}^{( 1 )} ( u ; g ) u + {f}^{( 2 )} ( u ; g ) {u}^{2} + {f}^{( 3 )} ( u ; g ) {u}^{3} + … ,$$

where the coefficients f⁽¹⁾(u; g), f⁽²⁾(u; g) and f⁽³⁾(u; g) are determined by the Taylor expansion so that the resonance frequency ω is given by:

$${ω}^{2} = \frac{k - {f}^{( 1 )} ( u ; g )}{m}$$

Since the coefficient f⁽¹⁾(u; g) depends on the size of the gap 50, the resonance frequency ω, changes when the gap width changes, in particular when the gap width changes due to mechanical stresses and/or deformation of the substrate 40. As a result, the width of the gap 50 can be sampled locally by means of resonators 10 spatially spaced apart from one another, in order in particular to thus recognize deformations of the substrate 40 or of a multilayer composite comprising the substrate 40.

Alternatively to the embodiment shown in FIGS. 4 and 5, the resonators 10, 11, 12 can also be suspended resiliently movably from an anchoring 25 rigidly connected to the substrate (cf. in particular FIG. 15). In this case, the resonators 10, 11, 12 do not move with the seismic mass 60 about the torsion axis 72.

FIG. 6A to 6D show exemplary and schematically different configurations that can be understood on the basis of the measuring principle presented here.

FIG. 6A shows a rest configuration or an ideal configuration, in which no mechanical stresses or deformations are present. In this case, the dynamic deflection gₐ of the first resonator 11 corresponds to the dynamic deflection g_{b} of the second resonator 12, gₐ=g_{b}=g₀. ωₐ=ω_{b}=ω₀ applies accordingly to the resonance frequencies ωₐ, ω_{b} of the first and second resonators.

FIG. 6B shows an asymmetrical deformation of the substrate 40. Accordingly, the dynamic deflection gₐ of the first resonator 11 is greater than in the rest position (gₐ>g₀), whereas the dynamic deflection g_{b} of the second resonator 12 is less than in the rest position (g_{b}<g₀). ωₐ>ω₀ and ω_{b}<ω₀ applies accordingly to the resonance frequencies ωₐ, ω_{b} of the first and second resonators 11, 12, respectively.

FIGS. 6C and 6D show symmetrical deformations of the substrate 40. The dynamic deflection gₐ of the first resonator 11 corresponds to the dynamic deflection g_{b} of the second resonator 12, i.e. gₐ=g_{b}. In the example of FIG. 6C, the dynamic deflection of the resonators 10, 11, 12 is greater than the rest position shown in FIG. 6A, i.e. gₐ=g_{b}>g₀ thus applies or, for the resonance frequencies, ωₐ=ω_{b}>ω₀. FIG. 6D shows a configuration in which the deformation of the substrate 40 results in a reduction in the gap width; in this case, ωₐ=ω_{b}<ω₀ applies accordingly.

Since the change in the resonance frequency ωₐ of the first resonator 11 or the change in the resonance frequency ω_{b} of the second resonator 12 is proportional to the size of the gap 50, both symmetrical and asymmetrical deformations of the substrate 40 can thus be detected.

The device 1 for detecting the disturbance variable can be realized by means of common processes in the multilayer composite of the MEMS sensor 100. In this case, the substrate 40 described above forms a layer in a multilayer structure of the MEMS sensor 100. The resonators 10, 11, 12 are laterally spaced apart from one another in a plane (xy-plane) parallel to the main extension plane of the substrate 40.

FIGS. 7, 8, and 9 schematically show a possible exemplary embodiment of a resonator 10 integrated in the multilayer composite of the MEMS sensor 100.

In the exemplary embodiment shown, the resonator 10 is designed as a beam, supported at one end, with a substantially rectangular cross-section, which is formed in a layer 110 of the MEMS sensor 100. Vibratable structural elements 15, in particular beams, supported at one end have proven to be advantageous for the resonators 10 since they have increased resonance frequency stability against internal stresses and process defects.

The shape of the resonator 10 is specified, for example, lithographically by means of a mask or, alternatively, is obtained by exposing holes or trenches in the layer 110, for example by etching.

Optionally provided in particular at a vibratable free end of the resonator 10 is a stopper 111, which can be produced, for example, by means of a further mask, in order to prevent the resonator 10 from being pulled into the electrode arrangement 30. This serves in particular to increase the robustness of the resonator 10 against voltage peaks and/or external mechanical influences, such as impacts.

The layer 110, in which the resonator 10 is formed, by way of example, as a substantially beam-shaped structural element 15 with a vibratable free end, is optionally connected via an intermediate layer 120 to a further layer 130 in which the electrode arrangement 30 is formed. The interconnected layers 110, 120, 130 form an anchoring for the resonator 10 so that said resonator can be put into vibration by applying voltage to the drive electrode 31.

The anchoring formed by the interconnected layers 110, 120, 130 is, for example, rigidly connected to the anchor 20 so that the movement of the resonators 10, 11, 12 is decoupled from the movement of the seismic mass 60. Alternatively, the anchoring formed by the interconnected layers 110, 120, 130 can be mounted as part of the seismic mass 60 on the anchor 20 so as to be movable about the torsion axis 72.

The drive electrodes 31 and the detection electrodes 32 of FIG. 7 to 9 extend substantially, i.e. in particular taking into account the manufacturing tolerances and in the absence of mechanical deformations and/or mechanical stresses, in a plane parallel to the main extension plane of the substrate 40.

FIG. 16 to 19 schematically show a further possible exemplary embodiment of a resonator 10 integrated in the multilayer composite of a MEMS sensor 100, which exemplary embodiment comprises an electrode arrangement 30 with drive electrodes 31 and detection electrodes 32 arranged opposite one another in the z-direction 1000. The drive electrodes 31 and the detection electrodes 32 are arranged opposite one another in two planes substantially parallel to the main extension plane. The resonators 10, 11, 12 are positioned in the intermediate region between the drive electrodes 31 and detection electrodes 32 such that they are spaced apart from the drive electrodes 31 and the detection electrodes 32 in the z-direction 1000.

The detection electrode 32, which takes the form of an upper electrode in the exemplary embodiment shown, is connected via a further intermediate layer 140 to the layer 110, in which the resonators 10, 11, 12 are formed. The exemplary embodiment of FIG. 16 to 19 substantially corresponds, i.e. in particular except for the arrangement and design of the electrode arrangement 30, to the arrangement already described with reference to FIG. 7 to 9, so that reference is made to the description in this respect.

In embodiments, it is provided that the position of the drive electrodes 31 and detection electrodes 32 varies. In particular, it may be provided that the position of the drive electrodes 31 and detection electrodes 32 is swapped around in comparison to the embodiment shown in FIG. 7 to 9 and/or in FIG. 16 to 19, so that, for example, the detection electrode 32 is arranged opposite the vibratable free end of the resonator 10, 11, 12.

FIG. 10 to 14 show a MEMS sensor 100, which in the exemplary embodiment shown is designed as an out-of-plane MEMS acceleration sensor with an asymmetrical rocker and is designed to compensate for systematic measurement deviations. The section plane shown in FIG. 11 is denoted by XI in FIG. 10. The MEMS sensor 100 shown comprises a conventional sensor device 90, which is designed to detect a measurement signal which depends on the position of the seismic mass 60 in relation to the sensor housing or the substrate 40.

In the example shown, the movable mass 60 is formed by a multilayer structure which comprises the layers 108, 109, 110. The multilayer structure formed from these layers is mounted so as to be rotatable about the torsion axis 72 in relation to the sensor housing. The resonators 10, 11, 12 are incorporated in the layer 110, i.e. the movement of the resonators 10, 11, 12 is coherent with the movement of the seismic mass 60.

The exemplary embodiment of FIG. 10 to 14 comprises a total of four resonators 10 which are spaced apart from one another and can be driven by means of the drive electrodes 31. For controlling the drive electrodes 31, they are connected to a control and evaluation unit 95 via a common drive channel 102 or via separate drive channels 102. Each resonator 10 is assigned a separate detection electrode 32. The resonators 10 are at the same electrical potential, which is achieved by connecting them to the same channel 105.

For detecting the disturbance variable dependent on the resonance frequency of the resonantly excited resonators 10, 11, 12, independent detection channels 101 are provided, which are assigned to the respective resonators 10, 11, 12 and are connected to the control and evaluation unit 95. The detected disturbance variable depends locally on the size or width of the gap 50 at the positions of the resonators 10, 11, 12 and is thus in particular a measure of any deformations or stresses.

For providing the capacitive measurement signal dependent on the position of the seismic mass 60, the sensor device 90 is connected to the control and evaluation unit 95 via further channels 103, 104. The further channels serve to capacitively detect the position of the seismic mass 60 and, for this purpose, in a conventional manner, tap capacitances from upper and lower electrodes 80a, 80b, 84a, 84b of the sensor device 90, from which capacitances the measurement signal can be derived.

The control and evaluation unit 95 is designed to compensate for systematic measurement deviations in the measurement signal of the sensor device 90 on the basis of the detected disturbance variable.

The resonators 10, 11, 12 of the exemplary embodiment shown are arranged in pairs on opposite sides of the torsion axis 72, in particular mirror-symmetrically with respect to the torsion axis 72.

FIG. 12 shows the MEMS sensor of FIG. 10 in detail in a perspective view, FIGS. 13 and 14 show a front and rear side of the MEMS sensor 100 of FIG. 10 with electrical contacting in the form of detection channels 101, drive channels 102 and further channels 102, 103. The detection channels 101 are provided for contacting the detection electrodes 32 assigned to the resonators 10, 11, 12. The drive channels 102 are arranged correspondingly for contacting the drive electrodes 31.

The configuration of the exemplary embodiment of FIG. 10 to 14 is easy to implement but measurement errors which are induced by the movement of the movable mass 60 may occur.

FIG. 15 shows a further exemplary embodiment in which the movement of the resonators 10 is decoupled from the kinematics of the seismic mass 60. For this purpose, the resonators 10, 11, 12 may, for example, be suspended resiliently from an anchoring 25 rigidly connected to the anchor 20.

In a method for compensating for systematic measurement deviations of the MEMS sensor 100, the resonators 10 are resonantly excited by means of the electrode arrangement 30 and a disturbance variable dependent on the resonance frequency of the resonantly excited resonators 10 is detected capacitively.

Systematic measurement deviations in the measurement signal of the sensor device 95, which measurement signal is a measure of a force acting on the movable mass 60, are compensated analogly or digitally on the basis of the detected disturbance variable. The detected disturbance variable, which is linked to the structural properties of the MEMS sensor 100 via the electrostatic spring-softening effect, depends on the resonance frequencies, in particular on frequency shifts of the resonantly vibrating resonators 10. In this way, deformations and stresses of the substrate or of the layer composite can thus in particular be detected in order to provide correspondingly compensated output signals which are corrected by these disturbance variables.

What is claimed is:

1. A micro-electromechanical system (MEMS) sensor, the MEMS sensor being a MEMS acceleration sensor or MEMS inertial sensor, the MEMS sensor comprising:
a substrate having a main extension plane;
a seismic mass suspended movably with respect to the substrate in at least a z-direction perpendicular to the main extension plane;
a sensor device configured to detect a measurement signal dependent on a position of the seismic mass in relation to the substrate;
at least two resonators which are suspended resiliently movably in the z-direction in relation to the substrate; and
a controllable electrode arrangement which is configured to resonantly excite each of the at least two resonators to generate mechanical resonant vibrations, and to capacitively detect a disturbance variable dependent on at least one resonance frequency of the resonant vibrations.

2. The MEMS sensor according to claim 1, wherein the at least two resonators are suspended resiliently movably from the seismic mass or are suspended resiliently movably from an anchoring rigidly connected to the substrate.

3. The MEMS sensor according to claim 1, wherein the seismic mass is a deflectable asymmetrical rocker which is anchored to the substrate via at least one torsion spring so as to be movable about a torsion axis.

4. The MEMS sensor according to claim 3, wherein the at least two resonators are arranged spaced apart from one another on opposite sides of the torsion axis, and mirror-symmetrically with respect to the torsion axis.

5. The MEMS sensor according to claim 1, wherein to each of the resonators is assigned a respective drive electrode and a respective detection electrode in such a way that each resonator can be resonantly excited using the respectively assigned drive electrode and a disturbance variable dependent on the resonance frequency of the resonantly excited resonator can be detected by means of the assigned detection electrode.

6. The MEMS sensor according to claim 5, wherein the respective drive electrodes and the respective detection electrodes are arranged in a plane substantially parallel to the main extension plane.

7. The MEMS sensor according to claim 5, wherein the respective drive electrodes and the respective detection electrodes are arranged opposite one another in two planes substantially parallel to the main extension plane, in such a way that the resonators are arranged between the respective drive electrodes and the respective detection electrodes and are spaced apart from the respective drive electrodes and the respective detection electrodes in the z-direction.

8. The MEMS sensor according to claim 1, wherein the resonators are structural elements resiliently suspended on one or both ends, substantially in the form of a beam or a finger or a piston or a fork, which extend substantially in parallel with the main extension plane.

9. The MEMS sensor according to claim 7, wherein the at least two resonators include at least three resonators which are laterally spaced apart from one another in a plane parallel to the main extension plane, in an arrangement which deviates from a collinear arrangement.

10. The MEMS sensor according to claim 1, further comprising:
a control and evaluation unit configured to control the electrode arrangement for the resonant excitation of the resonators and to compensate for systematic measurement deviations in the measurement signal of the sensor device depending on the detected disturbance variable.

11. A method for compensating for systematic measurement deviations of a micro-electromechanical system (MEMS) sensor, the MEMS sesnsor including a substrate having a main extension plane, a seismic mass suspended movably in relation to the substrate in at least a z-direction perpendicular to the main extension plane, and a sensor device which detects a measurement signal dependent on a position of the seismic mass in relation to the substrate, the method comprising:
resonantly exciting at least two resonators, which are suspended resiliently movably in the z-direction in relation to the substrate, to generate mechanical resonance vibrations;
capacitively detecting a disturbance variable dependent on a resonance frequency of the resonant vibrations; and
compensating, depending on the detected disturbance variable, systematic measurement deviations in the measurement signal of the sensor device.

12. The method according to claim 11, wherein the systematic measurement deviations in the measurement signal of the MEMS sensor are compensated analogly or digitally.

13. The method according to claim 11, wherein, for the resonant excitation of the resonators, a pulsed or continuous excitation signal, including a harmonic excitation signal or an excitation signal with a temporally variable frequency, is applied to the electrode arrangement to drive electrodes of the MEMS sensor.
